(19) United States
(12) Patent Application Publication
(10) Pub. No.: US 2013/0314822 A1
(43) Pub. Date: Nov. 28, 2013

(54) MOTOR PROTECTION RELAY TO OPTIMISE THE MONITORING AND PROTECTION OF AN ELECTRIC MOTOR

(71) Applicant: Berengere Dio, Laverune (FR)

(72) Inventor: Berengere Dio, Laverune (FR)

(73) Assignees: ALSTOM Technology Ltd., Baden (CH); Schneider Electric Protection & Controle, Lattes (FR)

(21) Appl. No.: 13/992,418

(22) PCT Filed: Dec. 5, 2011
(86) PCT No.: PCT/EP2011/071771

§ 371 Date: Aug. 12, 2013

(30) Foreign Application Priority Data
Dec. 8, 2010 (FR) 1060254

(51) Int. Cl. G01R 31/34; H02H 7/08

(52) U.S. Cl. CPC G01R 31/34; H02H 7/08
USPC 361/31; 702/33

(57) ABSTRACT

The invention concerns a monitoring method and system for monitoring an electric motor, comprising:

modelling means (5) for modelling a circle diagram (31) based on current intensities of said electric motor,

calculating means (7) for calculating at least one operational parameter by using said circle diagram, said operational parameter being anyone out of the following operational parameters: torque, resistive loss, rotor resistance, slip, and motor yield,

monitoring means (9) for monitoring said electric motor (3) based on said operational parameter.

### DISCLOSURE

1. Technical Field

The present invention concerns the general field of motor protection relays, and more particularly the monitoring of an electric motor.

2. State of the Prior Art

An electric motor may be protected from overload or excessive temperatures that may damage it. This protection is usually performed by a motor protection relay configured with appropriate setting values.

The motor protection relay is used to detect overload, short-circuits, and other faults and may be based on electromechanical or numerical techniques.

However, most of these motor protection relays need to be manually parameterized by the installer before being put into service, and cannot adapt themselves to each application of the electric motor.

Nevertheless, there exist motor protection relays based on built-in logic that can perform self-learning of some parameters of the motor to be protected so as to provide better protection and monitoring for electric motors.

An example of such protection relay is the General Electrics Multilin 369. It has got the ability to learn the following parameters of a specific motor: starting current, starting thermal capacity, acceleration time, cooling time constant, heating time constant, and average motor load. However some other motor induction representative parameters are not provided by such relays.

The problem to be solved by the present invention is therefore to propose a system that considers some of the specific operating characteristics of an electric motor for appropriately protecting it.

### DESCRIPTION OF THE INVENTION

The present invention is defined by a monitoring system for monitoring an electric motor, comprising:
modelling means for modelling a circle diagram based on current intensities of said electric motor,
calculating means for calculating at least one operational motor parameter by using said modelling of circle diagram,
monitoring means for monitoring said electric motor based on said operational parameter.

The circle diagram modelling or method is used to rapidly estimate operational motor parameters that provide meaningful motor running information for an optimal and efficient monitoring of the electric motor. The operational parameters give information about the functioning limitations of the motor and in particular, the maximum connected load that can be afforded by the motor.

Advantageously, said calculating means is intended to use the circle diagram to calculate anyone out of the following operational parameters: torque, resistive loss, rotor resistance, slip, and motor yield.

Thus, the monitoring system enables to perform self-learning of values representing the proper functioning of the motor.

As a variant, said calculating means is intended to directly calculate slip.

The invention concerns also a motor protection relay for protecting an electric motor comprising a monitoring system according to anyone of the above characteristics, said relay further comprising:
measuring means for measuring said current intensities,
detecting means for detecting an anomaly of the motor by analysing at least one of said operational parameters,
triggering means for switching off the power supply of the motor in case an anomaly is detected by said detecting means.

Said detecting means is intended to compare each operational parameter to a corresponding predetermined threshold and to send a command to the triggering means for switching off the power supply of the motor when an operational parameter attains its corresponding predetermined threshold.

The invention concerns also an electric motor equipped with a motor protection relay according to the above characteristics.

The electric motor further comprises a speed acquiring means for determining the rotor speed.

The invention concerns also a method for monitoring an electric motor, comprising the following steps:
constructing a circle diagram based on current intensities of said electric motor,
calculating at least one operational parameter by using said circle diagram,
monitoring said electric motor in function of said operational parameter.

The invention also concerns a computer program comprising code instructions for implementing the method of monitoring an electric motor according to the above characteristics, when it is executed by processing means.

### BRIEF DESCRIPTION OF THE DRAWINGS

Other characteristics and advantages of the invention will become apparent on reading a preferred embodiment of the invention given with reference to the appended figures amongst which:

FIG. 1 schematically illustrates a monitoring system for monitoring an electric motor, according to the invention;

FIG. 2 schematically shows a motor and a motor protection relay comprising the monitoring system of FIG. 1, and

FIG. 3 schematically illustrates the circle diagram enabling the determination of operational motor parameters by the monitoring system of FIG. 1.

### DETAILED DESCRIPTION OF PARTICULAR EMBODIMENTS

The present invention is based on using a circle diagram method within a motor protection relay for determining representative parameters of an operating motor and in particular, of an asynchronous motor.

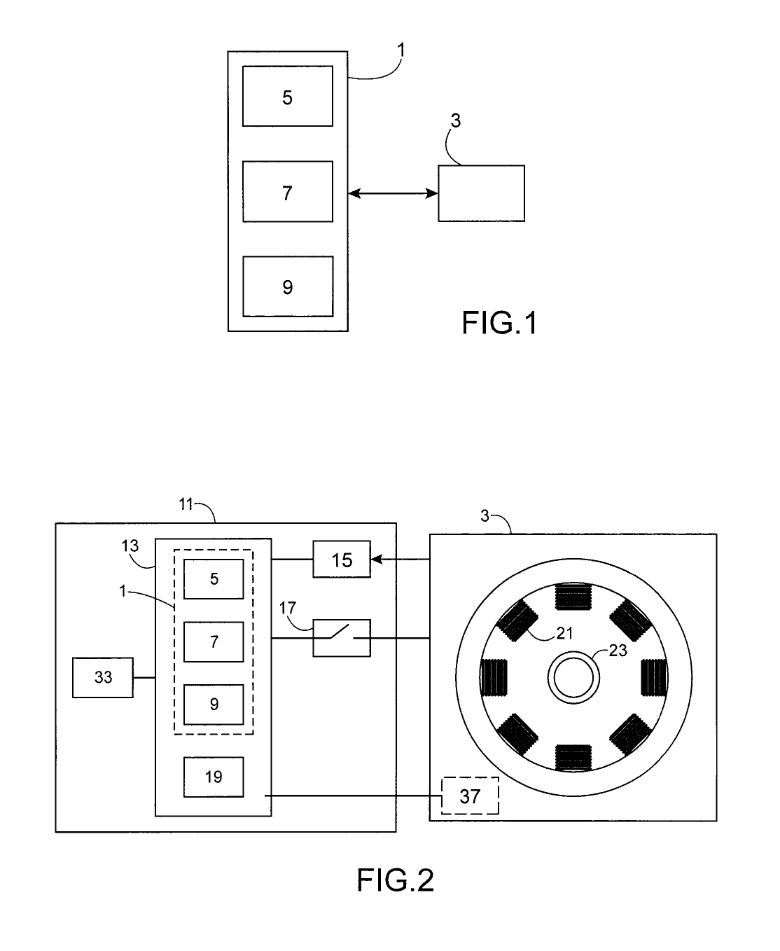

FIG. 1 schematically shows a monitoring system 1 for monitoring an electric motor 3, according to the present invention. The system comprises modelling means 5, calculating means 7, and monitoring means 9.

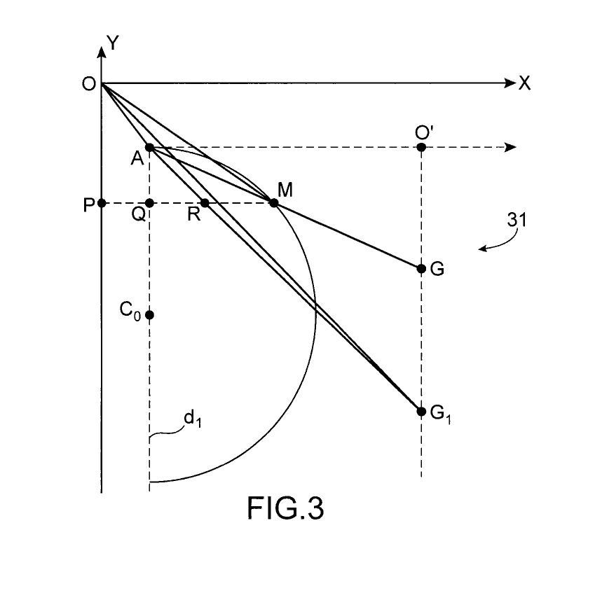

The modelling means 5 models a circle diagram (see FIG. 3) based on current intensities of the electric motor 3 such as no load current, load current, and blocked-rotor current.

The calculating means 7 calculates at least one operational parameter by using the circle diagram model.

Advantageously, the calculating means 7 is intended to calculate anyone out of the following set of operational parameters: torque, resistive loss, rotor resistance, slip, and yield of the motor. These parameters are representative of the functioning of the motor.

Indeed, the variation of the torque produced by the electric motor 3 gives a good indication about the operating mode of the motor 3 and may be used to diagnose excessive charge connected to the rotor and to avert damages or rotor overheating. The resistive loss by joule effect represents the warming-up of the motor 3 and gives an accurate representation of its thermal power dissipation. The slip gives accurate information about the proper functioning of the motor 3. The yield measures the efficiency of the motor 3 and corresponds to the ratio of the mechanical output power to the electrical input power supplied to the motor. Finally, the rotor resistance provides information about power dissipated by the motor 3.

Thus, the monitoring means 9 can efficiently monitor the electric motor 3 on the basis of at least one of these operational parameters.

It is to be noted that the modelling means 9, the calculating means 7, and the monitoring means 9 may all make part of a processing means.

FIG. 2 schematically shows a motor protection relay 11 coupled to the electric motor 3.

The motor protection relay 11 comprises processing means 13, measuring means 15, triggering means 17, detecting means 19, as well as the monitoring system 1 according to the present invention.

For example, the modelling 5, calculating 7, and monitoring 9 means of the monitoring system 1 may be constituted of algorithmic modules implemented by the processing means 13 of the motor protection relay 11. The detecting means 19 may also be constituted of an algorithmic module implemented by the processing means 13.

The measuring means 15 measures the current intensities of the electric motor 3. The detecting means 19 detects functioning anomalies of the electric motor 3 by analysing the operational parameters monitored by the monitoring system 1. Finally, the triggering means 17 are intended to switch off the power supply of the motor 3 when an anomaly has been detected. In particular, the detecting means 19 compares each operational parameter to a corresponding predetermined threshold and sends a command to the triggering means 17 for switching off the power supply of the motor 3 when at least one operational parameter attains its corresponding predetermined threshold. This enables to protect the motor 3 as well as associated mechanical systems from overloads, excessive temperatures, faults or any other factor that may damage the motor 3 or any other equipment.

The electric motor depicted in FIG. 2 is an induction motor of an asynchronous type composed of stator windings 21 arranged around the rotor 23. When a primary alternating current I₁ at a certain frequency w is supplied to the stator windings 21, a rotating magnetic field pattern is created that induces a secondary alternating current I₂ in the rotor 23.

The algorithm for determining the operational motor parameters within the motor protection relay 11 is illustrated in FIG. 3.

In particular, FIG. 3 schematically shows a circle diagram 31 constructed according to a method implemented by the monitoring system or by the processing means 13 of the motor protection relay 11.

At first the motor 3 is started under no load at a nominal frequency and a nominal voltage. The measuring means 15 measures the no load current intensity. In particular, it measures the stator RMS current and its angle at a steady state condition. These two values form a no load current vector \vec{OA} that can be easily reported on a two-dimensional coordinate system (O, X, Y) corresponding for example, to a complex plane.

Then, the motor 3 is started under load according to determined conditions chosen by the user. The measuring means 15 measures the load current (i.e., the stator RMS load current and its load angle). These two values form a load current vector \vec{OM} which is reported on the two-dimensional coordinate system (O, X, Y).

After having reported the two no load and load current vectors \vec{OA} and \vec{OM} on the coordinate system, the modelling means 9 constructs a circle with its centre C₀ on a line d₁ parallel to the Y-axis, and passing through the end points A and M of vectors \vec{OA} and \vec{OM} respectively. The circle diagram 31 is used by the processing means 13 for calculating the operating parameters and may eventually be traced on an output means 33 such as a screen.

The distance AM between the end points A and M (i.e., the magnitude of vector \vec{AM}) represents an RMS current I′₂ proportional to the induced secondary RMS rotor current I₂. In particular, the distance AM is given in function of the induced rotor current I₂, by the following formula:

$$AM = {I}_{2}^{′} = - \frac{μ}{{L}_{1}} {I}_{2} , \qquad$$

where L₁ is the stator self inductance and μ is the mutual inductance. It is to be noted that the value of AM is sufficient for determining some operational parameters without any need to individually determine the values of L₁ and μ.

Indeed, the resistive loss by joule effect P₂ can be determined by the calculating means 7 in function of the distance AM according to the following formula: P₂=3×AM²×R₂, where R₂ is the rotor resistance.

Moreover, points M and A may also be used to calculate the torque C of the electric motor 3 according to the following formula:

$$C = \frac{p}{w} QM ,$$

QM represents the distance between points Q and M, where Q is the intersection between lines (MP) and (AC₀) parallel to the X and Y axis respectively. In other terms, QM is the difference of abscissas between points M and A. On the other hand, w is the network frequency and p is the peer pole number of the motor 3.

Thus, the circle diagram method enables the resistive loss and the torque of the motor to be already calculated by using no load and load current intensities. Then, in order to calculate other operational parameters, the motor is started-up while maintaining the rotor blocked. The measuring means 15 measures then a blocked-rotor current represented by a stator current vector \vec{OG}₁ composed of stator RMS current and its corresponding angle under a short-circuited rotor current. The blocked-rotor current vector \vec{OG}₁ is then reported on the two-dimensional coordinate system (O, X, Y).

Advantageously, the blocked-rotor current vector may be used to calculate the rotor resistive loss by joule effect P₂ without needing to know the value of the rotor resistance R₂. In particular, the resistive loss P₂ is equal to the distance between point Q and a point R representing the intersection of lines (AG1) and (MP). The distance QR corresponds to the difference of abscissas between points A and R.

The resistive loss P₂ may then be used to calculate the rotor resistance R₂. In particular, the rotor resistance R₂ is determined in function of the distance between points A and M as well as the distance QR according to the following formula: R₂=QR/3AM².

The blocked-rotor current vector may also be used to calculate the slip S according to the following formula:

$$S = \frac{{O}^{′} G}{{O}^{′} {G}_{1}}$$

O′G₁ is the distance of point G₁ from the line (AO′) passing through A and parallel to the X-axis. Point G is the intersection between the lines (AM) and (O′G₁) and thus, O′G is the distance of point G from the line (AO′). In other words, O′ is the point of intersection between the line parallel to the Y-axis and passing through point G₁ and the line parallel to the X-axis and passing through point A.

In such conditions, the slip S is equal to unity and thus for other conditions, the slip can be simply measured on the O′G₁-axis (i.e. S=O′G). Thus, the circle diagram 31 enables the determination of the slip S without needing any speed sensor.

It is to be noted that some motors don't have the possibility to perform a blocked-rotor start-up. In that case, the slip may be directly calculated in function of the rotor speed N and thus, the other parameters may be calculated by still using the circle diagram.

The slip S is defined as the ratio between the relative speed of the magnetic field as seen by the rotor 23 to the speed of the rotating stator field. Thus, it may be directly calculated according to the following formula:

$$S = 1 - \frac{N}{Ns} ,$$

where N is the rotor speed and Ns is the synchronous speed of the magnetic field. In particular, Ns corresponds to the theoretical unloaded speed with no slip, which is controlled by the peer pole number and the network frequency.

Thus, in the case the electric motor is equipped with a speed determining means 37 for determining the rotor speed, the motor protection relay 11 may be connected to the speed determining means 37 so as to receive the rotor speed value.

It is to be noted that the speed determining means 37 may correspond either to a speed sensor that directly measures the rotor speed or to an estimating means that calculates the rotor speed.

Moreover, the calculating means 7 is intended to use the circle diagram 31 to calculate the motor efficiency or yield according to the following formula:

$$η = \frac{RM}{PM}$$

Point R is the intersection between the lines (AG1) and (PM) and thus, η can be easily calculated by dividing the distance between point M and the line (AG1) by the distance between the same point M and the Y-axis.

It should be noted that the processing means 13 comprised in the motor protection relay 11 can be used for executing a computer program comprising instruction codes, designed to implement the method of determining operational motor parameters by using the circle diagram 31 method according to the invention.

1. A monitoring system for monitoring an electric motor, characterised in that it comprises:
modelling means (5) for modelling a circle diagram (31) based on current intensities of said electric motor,
calculating means (7) for calculating at least one operational parameter by using said circle diagram, said operational parameter being anyone out of the following operational parameters: torque, resistive loss, rotor resistance, slip, and motor yield,
monitoring means (9) for monitoring said electric motor (3) based on said operational parameter.

2. The monitoring system according to claim 1, wherein said calculating means (7) is intended to calculate slip in function of the rotor speed of the motor (3).

3. A motor protection relay for protecting an electric motor comprising a monitoring system according to claim 1, said relay further comprising:
measuring means (15) for measuring said current intensities,
detecting means (19) for detecting an anomaly of the motor (5) by analysing at least one of said operational motor parameters, and
triggering means (17) for switching off the power supply of the motor (3) in case an anomaly is detected by said detecting means (19).

4. The relay of claim 3, wherein said detecting means (19) is intended to compare each operational parameter to a corresponding predetermined threshold and to send a command to the triggering means (17) for switching off the power supply of the motor (3) when an operational parameter attains its corresponding predetermined threshold.

5. An electric motor equipped with a motor protection relay (11) according to claim 4.

6. The electric motor of claim 5, further comprising a speed determining means (37) for determining the rotor speed N.

7. A method for monitoring an electric motor, characterised in that it comprises the following steps:
constructing a circle diagram (31) based on current intensities of said electric motor,
calculating at least one operational motor parameter by using said circle diagram,
monitoring said electric motor (3) in function of said operational parameter.

8. Computer program comprising code instructions for implementing the method of monitoring an electric motor according to claim 7, when it is executed by processing means.
